(19) United States
(12) Patent Application Publication
(10) Pub. No.: US 2006/0104461 A1
(43) Pub. Date: May 18, 2006

(54) Apparatus and method for decreasing the blocking capacitor in an audio system

(76) Inventor: Keven D. Coates, Cypress, TX (US)

Correspondence Address: TEXAS INSTRUMENTS INCORPORATED, P O BOX 655474, M/S 3999, DALLAS, TX, 75265, US

(21) Appl. No.: 10/987,742

(22) Filed: Nov. 12, 2004

(51) Int. Cl. H03G 5/00

(52) U.S. Cl. 381/98; 381/99; 381/111

(57) ABSTRACT

In an audio unit in which the audio signals are processed by processing unit and applied to an audio output unit through a blocking capacitor, the value of the blocking capacitor can reduced and the frequency response maintained by providing low frequency compensation. The low frequency compensation is provided by an FIR or IIR filter, the parameters of the FIR or IIR filter being adjusted for the appropriate compensation.

### BACKGROUND OF THE INVENTION

1. Field of the Invention

This invention relates generally to portable, digitized audio systems and, more particularly, to the capacitor component coupling a processing unit and an audio output unit.

2. Background of the Invention

The use of portable electronic devices has continued to increase over the past several years. In particular, the portable audio devices have continued to become ever more popular. Referring to FIG. 1, a block diagram of a portable audio device is shown. A storage media 11 or a receiver unit 12 apply signals with audio content to the processing unit 14. The audio content can be encoded or can be modulated in the signals applied to the processing unit 14. The processing unit 14 processes the applied signals and provides an audio output that can be applied to the audio output unit 19. The audio output unit 19 then provides audio output signals that can be heard by a user.

FIG. 1 also illustrates a further feature of portable audio systems. In many audio systems, a blocking capacitor 18 is needed to block a DC current from reaching the audio output unit and thereby compromising the signal available by the user. Referring to FIG. 2, an idealized frequency response of the audio output signal for two values of capacitance is shown. As will be clear from FIG. 2, the roll-off (deterioration) of low frequency signals occurs at a higher frequency for the lower capacitance. However, the larger the capacitance, the more space is needed and the more expense is added to each audio unit 10.

A need has therefore been felt for apparatus and an associated method for improving a portable audio unit. It would be yet another feature of the apparatus and associated method to reduce the value of the blocking capacitor. It would be a further feature of the apparatus and associated method to reduce the value of the blocking capacitor in an audio unit without compromising the low frequency response of the audio unit. It would be a more particular feature of the apparatus and associated method to provide compensation for low frequency deterioration of the audio signal resulting from the reduction in the blocking capacitance of the audio unit. It would be a still more particular feature of the apparatus and associated method to include a finite impulse response (FIR) or an infinite impulse response (IIR) filter in the processing unit and adjust the parameters of the FIR or IIR filter to compensate for at least a portion of the deterioration of the audio unit low frequency response resulting from the lowering of the value of the blocking capacitor.

### SUMMARY OF THE INVENTION

The aforementioned and other features are accomplished, according to the present invention, by including in the processing unit an FIR or IIR filter. The parameters of the FIR or IIR filter are selected to augment the low frequency response of the audio unit low frequency response thereby compensating for the deterioration in the low frequency response resulting from the incorporation of the blocking capacitor with a lower value of the capacitance.

Other features and advantages of present invention will be more clearly understood upon reading of the following description and the accompanying drawings and the claims.

### BRIEF DESCRIPTION OF THE DRAWINGS

FIG. 1 is block diagram of the audio unit according to the related art.

FIG. 2 illustrates how the frequency roll-off is determined by the value of the blocking capacitance.

FIG. 3 is a block diagram of the audio unit according to the present invention.

FIG. 4 illustrates how the FIR filter or an infinite impulse filter (IIR) compensates for the low frequency response of the audio unit.

### DESCRIPTION OF THE PREFERRED EMBODIMENT

### 1. Detailed Description of the Figures

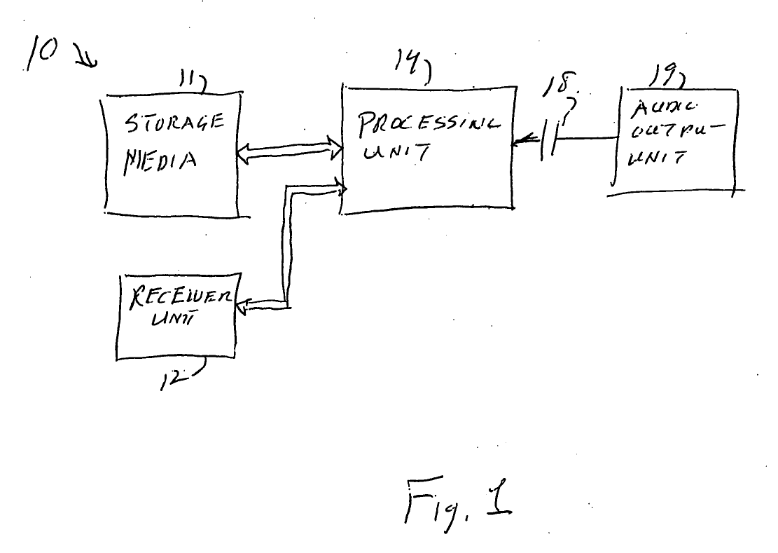

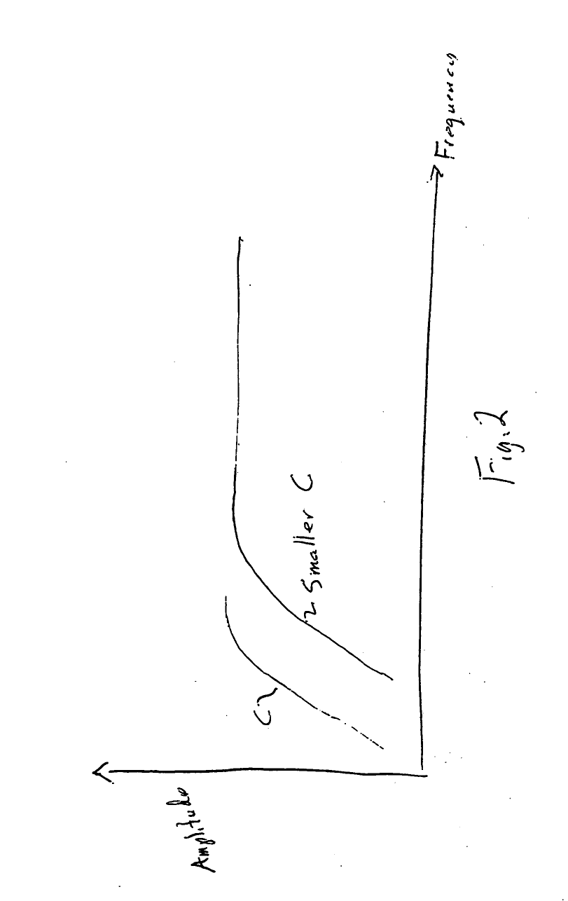

FIG. 1 and FIG. 2 have been discussed with respect to the prior art.

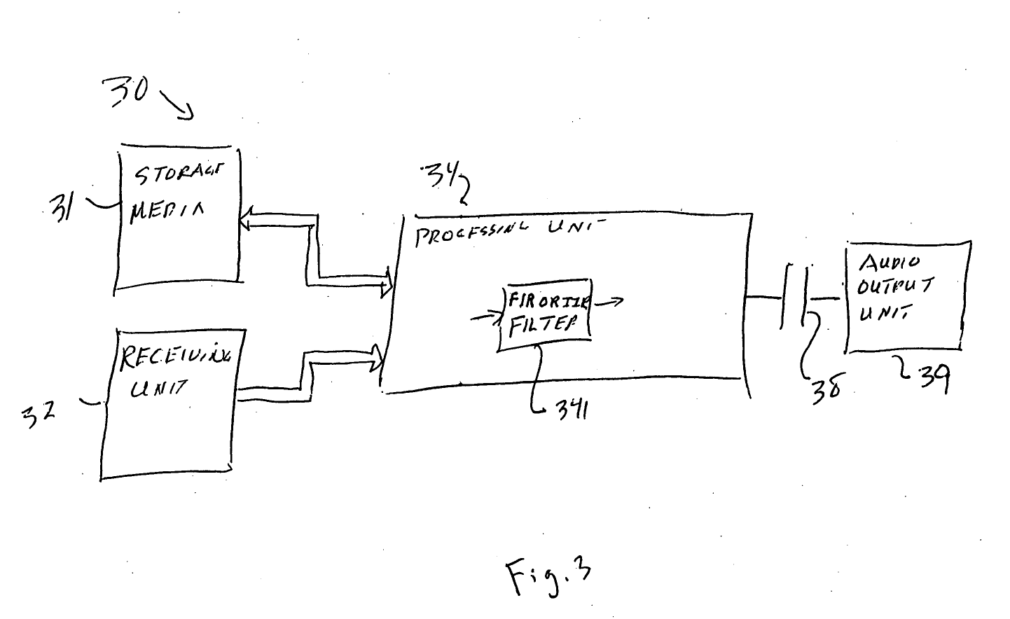

Referring now to FIG. 3, the audio unit 30, according to the present invention, is shown. As with the audio unit 10 shown in FIG. 1, the audio unit 30 includes a storage media 31 and a receiver unit 32 applying signals to processing unit 34. The processing unit 34 applies audio signals through the blocking capacitor 38 to the audio output unit 39. The audio output unit 39 can be a headphone set, a loud speaker component, etc. The processing unit 34 includes FIR or IIR filter 341. The FIR or IIR filter has the well-known feature that the parameters can be adjusted to control the frequency response. In the preferred embodiment, the processing unit is programmable and therefore able to accommodate a range of blocking capacitor values. When the blocking capacitor and other parameters of the audio system are known, the parameters can be determined in the FIR or IIR filter program.

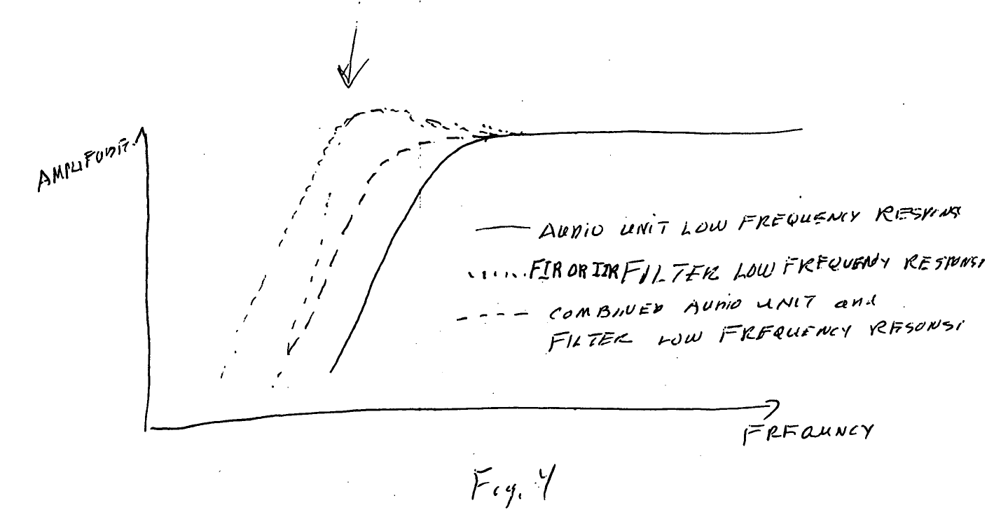

Referring to FIG. 4, an idealized example of how the FIR or IIR filter can be used to permit a lower capacitance value for the blocking capacitor. The solid line illustrates an idealized version of low frequency response of the audio unit. The dotted line represents the idealized low frequency response of the FIR or IIR filter. The dashed line represents the combination of the audio unit response and FIR or IIR filter low frequency response, i.e., the frequency response of the audio signals applied to the audio output unit.

### 2. Operation of the Preferred Embodiment

In the present invention, an FIR or IIR filter is used to compensate for a reduced value of a blocking capacitor and to extend the low frequency response available to the user. By using the FIR or IIR filter with appropriate parameters, the blocking capacitor can be decreased in value, thereby providing a similar or superior performance, but at a lower cost. As will be clear to those skilled in the art of FIR or IIR filters that as a practical matter, there are limitations to the amount of compensation that can be provided.

While the reduction of the blocking capacitor has been described with respect to an FIR or IIR filter, in the event that the input signals to the processing unit are in the frequency domain or converted thereto, then selective amplification of the appropriate frequency domain components can provide a similar result.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

What is claimed is:

1. An audio unit, the unit comprising:
a signal source;
a processing unit responsive to input signals from the signal source, the processing unit providing audio signals;
a blocking capacitor;
an audio output unit, the audio signals being applied through the blocking capacitor to the audio unit;
a low frequency compensation device in the processing unit, wherein the low frequency compensation device permits the use of a lower value for the blocking capacitance.

2. The unit as recited in claim 1 wherein the low frequency compensation device is an FIR or IIR filter.

3. The unit as recited in claim 2 wherein the FIR or IIR filter is a programmable FIR or IIR filter.

4. The unit as recited in claim 1 wherein the low frequency compensation is performed by controlling the magnitude of frequency components.

5. A method for compensating for a reduction in the value of a blocking capacitor, the method comprising:
augmenting the low frequency components of a digitized signal, the augmenting of the low frequency components selected to compensate for the deterioration of low frequency components as a result of a decreased blocking capacitor value.

6. The method as recited in claim 5 wherein the augmenting step is performed in a processing unit by an FIR or IIR filter.

7. The method as recited in claim 6 wherein the FIR or IIR filter parameters are programmable.

8. The method as recited in claim 5 further comprising:
multiplying selected low frequency components to compensate for a decreased blocking capacitor value.

9. The method as recited in claim 8 further comprising converting input signals to the frequency domain signals.

10. In a digitized audio system in which a processing unit applies audio signals through a blocking capacitor to an audio output unit, an implementation for compensating for a decreased value of the blocking capacitor, the implementation comprising:
an FIR or IIR filter or an infinite impulse filter (IIR), the parameters of the FIR filter or an infinite impulse filter (IIR) being selected to enhance the low frequency range that was compromised by the lower value of the blocking capacitor.

11. The implementation as recited in claim 10 wherein the parameters of the FIR or IIR filter are programmable.
